(19) United States
(12) Patent Application Publication
(10) Pub. No.: US 2010/0052111 A1
(43) Pub. Date: Mar. 4, 2010

(54) STACKED-CHIP DEVICE

(75) Inventor: Yukihiro Urakawa, Kawasaki-shi (JP)

Correspondence Address: SPRINKLE IP LAW GROUP, 1301 W. 25TH STREET, SUITE 408, AUSTIN, TX, 78705, US

(73) Assignee: Kabushiki Kaisha Toshiba, Tokyo (JP)

(21) Appl. No.: 12/546,109

(22) Filed: Aug. 24, 2009

(30) Foreign Application Priority Data
Aug. 26, 2008 (JP) 2008-216822

(51) Int. Cl. H01L 23/48

(52) U.S. Cl. 257/621; 257/690; 257/E23.011

(57) ABSTRACT

A stacked chip device includes a first chip having a first function, and a second chip having a second function which is different from the first function, which is stacked on the first chip. The first chip is a through-silicon-via chip which is comprised of a first semiconductor substrate having first and second surfaces, a first semiconductor integrated circuit which is provided on the first surface of the first semiconductor substrate, a first conductive layer connecting to the first semiconductor integrated circuit, which goes through the first surface of the first semiconductor substrate to the second surface of the first semiconductor substrate, and a second conductive layer not connecting to the first semiconductor integrated circuit, which goes through the first surface of the first semiconductor substrate to the second surface of the first semiconductor substrate. The first and second conductive layers have the same shape and the same structure.

### CROSS-REFERENCE TO RELATED APPLICATIONS

This application is based upon and claims the benefit of priority from prior Japanese Patent Application No. 2008-216822, filed Aug. 26, 2008, the entire contents of which are incorporated herein by reference.

### BACKGROUND OF THE INVENTION

1. Field of the Invention

The present invention relates to a through-silicon via.

2. Description of the Related Art

A chip-on-chip (CoC) technique is well known as a technique of realizing miniaturization and speed enhancement of an LSI. In the CoC technique, chips having different functions are stacked and accommodated in a single package.

In CoC, an electrical connection between the chips is established by a bump or a bonding wire. One of the problems with CoC is that electrical connections cannot be established by bumps alone when more than two chips are accommodated in a package, and performance decreases while production cost increases as the number of chips is increased.

In order to solve this problem, a technique in which electrical connection between the stacked chips is effected by a via pierced through a silicon substrate has been developed as an improved CoC technique (for example, see Jpn. Pat. Appln. KOKAI Publication Nos. 2005-217071 and 2002-76247).

In the specification, the technique is referred to as “through-silicon via” (TSV), and the chip used in the technique is referred to as a “through-silicon-via chip”. Although the word “silicon” is included in these terms, the word “silicon” expresses a generic term, and obviously the use of these terms does not mean that only the silicon chip is targeted.

With TSV, for example, because a signal is transmitted between the chips in a package by the via pierced through the silicon substrate, even if the number of chips in the package becomes three or more, bonding wires are not required to electrically connect the chips. Therefore, performance does not decrease nor production cost increase as the number of chips in a package is increased.

For this reason, TSV is a very promising technique for realizing multifunctional electronic devices in the near future.

However, in cases where TSV is applied to an actual product, it is necessary to study specifications, such as the function and layout of the vias pierced through the silicon substrate, which are suitable to the product, according to the kinds of chips accommodated in a package.

### BRIEF SUMMARY OF THE INVENTION

A through-silicon-via chip according to an aspect of the present invention comprises a semiconductor substrate having first and second surfaces, a semiconductor integrated circuit which is provided on the first surface of the semiconductor substrate, a first conductive layer connecting to the semiconductor integrated circuit, which goes through the first surface of the semiconductor substrate to the second surface of the semiconductor substrate, and a second conductive layer not connecting to the semiconductor integrated circuit, which goes through the first surface of the semiconductor substrate to the second surface of the semiconductor substrate. The first and second conductive layers have the same shape and the same structure.

A stacked chip device according to an aspect of the present invention comprises a first chip having a first function, and a second chip having a second function which is different from the first function, which is stacked on the first chip. The first chip is a through-silicon-via chip which is comprised of a first semiconductor substrate having first and second surfaces, a first semiconductor integrated circuit which is provided on the first surface of the first semiconductor substrate, a first conductive layer connecting to the first semiconductor integrated circuit, which goes through the first surface of the first semiconductor substrate to the second surface of the first semiconductor substrate, and a second conductive layer not connecting to the first semiconductor integrated circuit, which goes through the first surface of the first semiconductor substrate to the second surface of the first semiconductor substrate. The first and second conductive layers have the same shape and the same structure. The second chip is a chip which is comprised of a second semiconductor substrate having first and second surfaces, and a second semiconductor integrated circuit which is provided on the first surface of the second semiconductor substrate. The second conductive layer of the first chip is connected to the second integrated circuit of the second chip.

### BRIEF DESCRIPTION OF THE SEVERAL VIEWS OF THE DRAWING

FIG. 1 shows TSV;

FIG. 2 shows TSV of a first embodiment;

FIG. 3 shows TSV of a second embodiment;

FIG. 4 shows TSV of a third embodiment;

FIG. 5 shows TSV of a fourth embodiment;

FIG. 6 shows TSV of a fifth embodiment; and

FIGS. 7A and 7B show TSV of a sixth embodiment.

### DETAILED DESCRIPTION OF THE INVENTION

A stacked-chip device of an aspect of the present invention will be described below in detail with reference to the accompanying drawings.

### 1. OUTLINE

TSV is based on the CoC technique in which the chips are stacked and accommodated in one package. In cases where at least three chips having different functions are stacked, generally the stacking order is determined in consideration of chip sizes.

For example, in cases where a control chip (such as a CPU), a memory chip (volatile memory such as DRAM and nonvolatile memory such as a flash memory), and a voltage regulator module (VRM) chip are stacked, the control chip is disposed in the lowermost position, the VRM chip is disposed in the uppermost position, and the memory chip is disposed between the control chip and the VRM chip.

On the other hand, it is not realistic that all the stacked chips are formed into the through-silicon-via chip. Therefore, for example, the memory chip is formed into the through-silicon-via chip and other logic chips such as the control chip and the VRM chip are formed into a general-purpose structure (structure that does not have TSV).

In these situations, sometimes the uppermost chip and the lowermost chip are connected to each other while a semiconductor integrated circuit in the intermediate chip is not interposed therebetween.

For example, the VRM chip and the control chip are directly connected, because the VRM chip has been developed in order to stably supply a power supply voltage to a semiconductor integrated circuit in the control chip to improve reliability of the semiconductor integrated circuit.

However, there is no means for directly connecting the VRM chip and the control chip in the memory chip disposed between the VRM chip and the control chip. Therefore, a path through which the power supply voltage is supplied from the outside to the VRM chip and a path through which the power supply voltage is supplied from the VRM chip to the control chip depend on the bonding wire.

In an embodiment of the invention, a dummy through-silicon via (conductive layer) is made in the intermediate chip disposed between the uppermost chip and the lowermost chip, and the dummy through-silicon via is not connected to the semiconductor integrated circuit in the intermediate chip. The dummy through-silicon via has the same shape and structure as the through-silicon via (conductive layer) that should intrinsically be provided in the intermediate chip.

That is, an element, such as an alignment mark, which does not act as the via is removed from the dummy through-silicon via.

Therefore, the uppermost chip (for example, VRM chip) and the lowermost chip (for example, control chip) are directly connected through the dummy through-silicon via of the intermediate chip disposed therebetween, so that practical use of TSV can be realized.

As already defined, the semiconductor substrate that is one of the components of TSV is not limited to the silicon substrate.

### 2. THROUGH-SILICON VIA

The through-silicon via on which the invention is premised will be described.

FIG. 1 outlines the through-silicon via.

Chips L1, M1, M2, and 12 having different functions are mounted on a package board 10. For example, a ball grid array (BGA) terminal 11 is disposed in a lower surface of the package board 10.

Chip L1 is the control chip (for example, a CPU). Control chip L1 is connected to a conductive line C on the package board 10 through a bonding wire 15.

Chips M1 and M2 are the memory chip. Memory chip M1 is stacked on control chip L1, and memory chip M2 is stacked on memory chip M1.

Memory chips M1 and M2 are the through-silicon-via chip. Each of memory chips M1 and M2 includes the semiconductor substrate, a semiconductor integrated circuit E1, and a conductive layer 14. Semiconductor integrated circuit E1 is formed on one surface side of the semiconductor substrate. The conductive layer 14 is pierced from one surface side of the semiconductor substrate to the other surface side, and connected to semiconductor integrated circuit E1.

Bumps 13 are disposed between control chip L1 and memory chip M1 and between memory chip M1 and memory chip M2.

Chip 12 is the VRM chip. The VRM chip 12 is disposed on memory chip M2 with a spacer (for example, insulating material) 16 interposed therebetween.

The VRM chip 12 is connected to the conductive line C on the package board 10 by the bonding wire 15.

At this point, semiconductor integrated circuit E1 is defined as follows. The definition is also used in the following embodiments.

Semiconductor integrated circuit E1 means all integrated circuits that are formed on one surface side of the semiconductor substrate. That is, in cases where the conductive layer (through-silicon via) 14 is connected to one of the integrated circuits although the integrated circuits are not correlated with one another, it is defined that the conductive layer 14 is the conductive layer connected to semiconductor integrated circuit E1.

In TSV, control chip L1 and at least two memory chips M1 and M2 disposed on control chip L1 can be electrically connected without the use of a bonding wire.

The signal transmission and electrical supply are performed between control chip L1 and memory chips M1 and M2 using the through-silicon via (conductive layer) pierced from one surface side of the semiconductor substrate to the other surface side, so that reduction of package size, high-speed signal transmission, and suppression of power supply voltage drop in a chip can be achieved.

However, the through-silicon via in memory chips M1 and M2 is connected to semiconductor integrated circuit E1 in memory chips M1 and M2. Therefore, because memory chips M1 and M2 do not have means for directly connecting control chip L1 and the VRM chip 12, the VRM chip 12 is connected to the conductive line C on the package board 10 by the bonding wire 15.

### 3. EMBODIMENT

### (1) First Embodiment

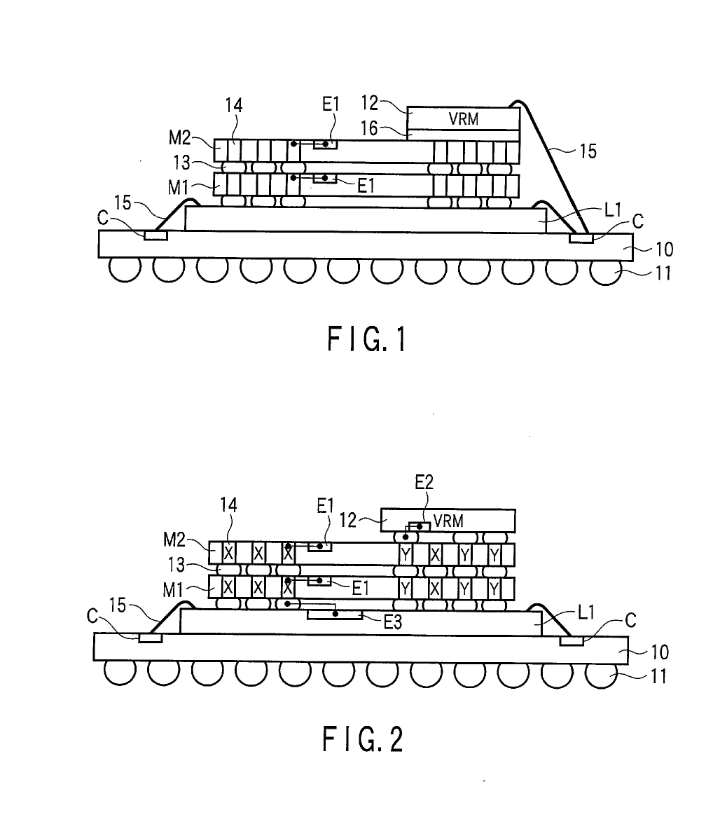

FIG. 2 shows a through-silicon via according to a first embodiment of the invention.

Chips L1, M1, M2, and 12 having different functions are mounted on the package board 10. For example, the BGA terminal 11 is disposed in the lower surface of the package board 10.

Chip L1 is the control chip (for example, CPU). Control chip L1 is connected to the conductive line C on the package board 10 through the bonding wire 15.

Chips M1 and M2 are the memory chip. Memory chip M1 is stacked on control chip L1, and memory chip M2 is stacked on memory chip M1.

Chip 12 is the VRM chip. The VRM chip 12 is stacked on memory chip M2.

The bumps 13 are disposed between control chip L1 and memory chip M1, between memory chip M1 and memory chip M2, and between memory chip M2 and the VRM chip 12.

Memory chips M1 and M2 are the through-silicon-via chip. Each of memory chips M1 and M2 includes the semiconductor substrate, semiconductor integrated circuit E1, a conductive layer 14(X), and a conductive layer 14(Y). Semiconductor integrated circuit E1 is formed on one surface side of the semiconductor substrate. Conductive layer 14(X) is pierced from one surface side of the semiconductor substrate to the other surface side, and connected to semiconductor integrated circuit E1. Conductive layer 14(Y) is pierced from one surface side of the semiconductor substrate to the other surface side, and not connected to semiconductor integrated circuit E1.

The feature of the through-silicon-via chip is that conductive layer 14(Y) is provided.

Although conductive layer 14(Y) has the same shape and structure as conductive layer 14(X), conductive layer 14(Y) is not connected to semiconductor integrated circuit E1 in each of memory chips M1 and M2. Hereinafter, conductive layer 14(Y) is referred to as a dummy through-silicon via.

Conductive layer 14(Y) that is the dummy through-silicon via has a function of directly connecting control chip L located immediately below memory chips M1 and M2 and the VRM chip 12 located immediately above memory chips M1 and M2.

The signal transmission and electric supply are performed between control chip L1 and the VRM chip 12 using conductive layer 14(Y) that is the dummy through-silicon via.

For example, the power supply potential is supplied from the package board 10 to control chip L1 through the bonding wire 15, and supplied from control chip L1 to the VRM chip 12 or from the VRM chip 12 to control chip L1 through conductive layer 14(Y).

An element (for example, alignment mark) which does not act as the via is removed from the dummy through-silicon via.

The VRM chip 12 is connected to memory chip M2 by flip-chip bonding while one surface side on which a semiconductor integrated circuit E2 is formed is placed in a downward direction (flip-chip structure).

On the other hand, in memory chips M1 and M2, one surface side on which semiconductor integrated circuit E1 is formed is placed in an upward direction (side of the VRM chip 12). Alternatively, in memory chips M1 and M2, one surface side on which semiconductor integrated circuit E1 is formed may be placed in the downward direction (side of control chip L1).

Conductive layer 14(Y) of each of memory chips M1 and M2 is connected to semiconductor integrated circuit E2 on one surface side of the VRM chip 12, and conductive layer 14(X) of each of memory chips M1 and M2 is connected to a semiconductor integrated circuit E3 on one surface side of control chip L1.

In TSV of the first embodiment, control chip L1 and at least two memory chips M1 and M2 disposed on control chip L1 can electrically be connected without the use of a bonding wire.

The signal transmission and electric supply are performed between control chip L1 and memory chips M1 and M2 using conductive layer 14(X) pierced from one surface side of the semiconductor substrate to the other surface side, so that reduction of package size, high-speed signal transmission, and suppression of power supply voltage drop in the chip can be achieved.

Control chip L1 and the VRM chip 12 are directly connected through conductive layer 14(Y) in each of memory chips M1 and M2 disposed between control chip L1 and the VRM chip 12, so that practical use of TSV can be realized.

### (2) Second Embodiment

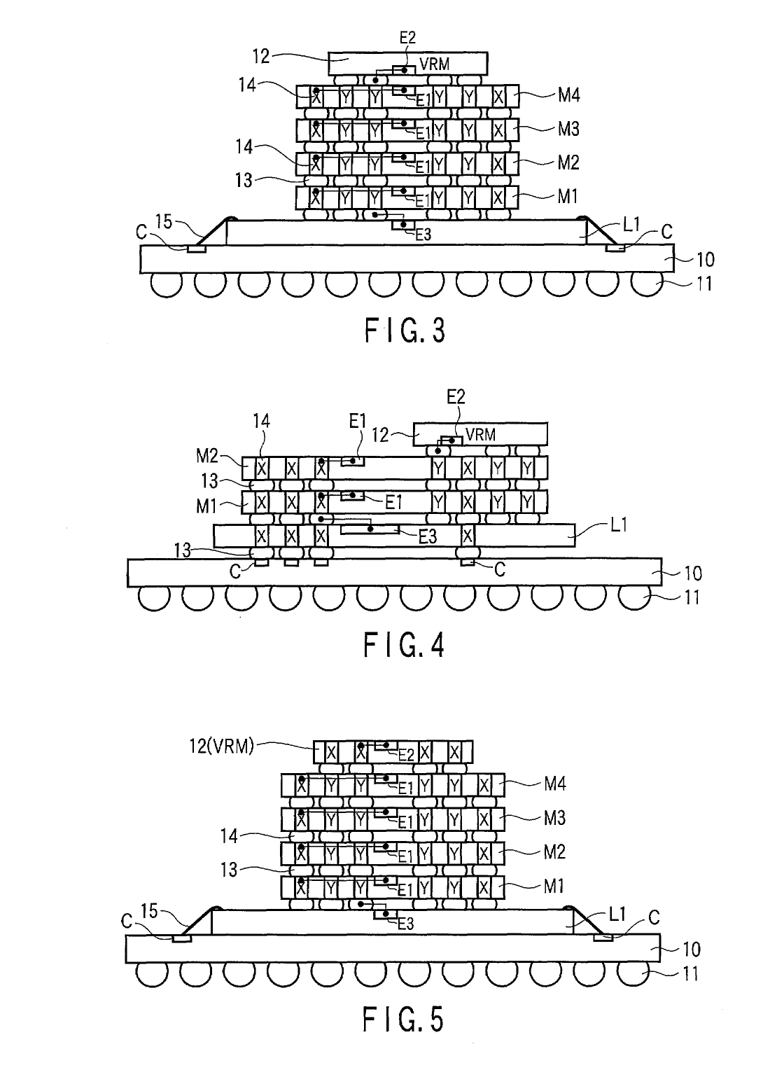

FIG. 3 shows a through-silicon via according to a second embodiment of the invention.

The second embodiment relates to an application example of the first embodiment.

TSV of the second embodiment differs from TSV of the first embodiment in the number of memory chips (M1 to M4) stacked on control chip L1 and the position of the VRM chip 12.

In TSV, there is no limitation to the number of memory chips stacked on control chip L1. In the second embodiment, four memory chips M1 to M4 are stacked on control chip L1. Preferably the number of memory chips stacked on control chip L1 is 2ⁿ (n is a natural number).

In the second embodiment, the VRM chip 12 is disposed in the centers of memory chips M1 to M4. The layouts of conductive layers 14(Y) that are the dummy through-silicon via in memory chips M1 to M4 are determined such that the VRM chip 12 can be disposed in the centers of memory chips M1 to M4.

### (3) Third Embodiment

FIG. 4 shows a through-silicon via according to a third embodiment of the invention.

The third embodiment also relates to an application example of the first embodiment.

TSV of the third embodiment differs from TSV of the first embodiment in that control chip (for example, CPU) L1 is the through-silicon-via chip.

Control chip L1 includes the semiconductor substrate, semiconductor integrated circuit E3, and conductive layer 14(X). Semiconductor integrated circuit E3 is formed on one surface side of the semiconductor substrate. Conductive layer 14(X) is pierced from one surface side of the semiconductor substrate to the other surface side, and connected to semiconductor integrated circuit E3.

Semiconductor integrated circuit E3 in control chip L1 is connected to semiconductor integrated circuit E1 in each of memory chips M1 and M2 through conductive layer 14(X) in each of memory chips M1 and M2.

Semiconductor integrated circuit E3 in control chip L1 is connected to the conductive line C on the package board 10 through conductive layer 14(X) in control chip L1.

In control chip L1, one surface side on which semiconductor integrated circuit E3 is formed is placed in the upward direction (side of memory chip M1). Alternatively, in control chip L1, one surface side on which semiconductor integrated circuit E3 is formed may be placed in the downward direction (side of the package board 10).

In such cases, the signal transmission and electric supply are also performed between control chip L1 and the VRM chip 12 using conductive layer 14(Y) that is the dummy silicon via.

For example, the power supply potential is supplied from the package board 10 to control chip L1 through conductive layer 14(X), and supplied from control chip L1 to the VRM chip 12 or from the VRM chip 12 to control chip L1 through conductive layer 14(Y).

Thus, in the third embodiment, control chip L1 can also be formed into the through-silicon-via chip. In this case, control chip L1 and the conductive line C on the package board 10 can be connected by the bump 13.

### (4) Fourth Embodiment

FIG. 5 shows a through-silicon via according to a fourth embodiment of the invention.

The fourth embodiment relates to an application example of the second embodiment.

TSV of the fourth embodiment differs from TSV of the second embodiment in that the VRM chip 12 is the through-silicon-via chip.

The VRM chip 12 includes the semiconductor substrate, semiconductor integrated circuit E2, and conductive layer 14(X). Semiconductor integrated circuit E2 is formed on one surface side of the semiconductor substrate. Conductive layer 14(X) is pierced from one surface side of the semiconductor substrate to the other surface side, and connected to semiconductor integrated circuit E2.

Semiconductor integrated circuit E2 in the VRM chip 12 is connected to semiconductor integrated circuit E3 in control chip L1 through conductive layer 14(X) in the VRM chip 12 and conductive layer 14(Y) in each of memory chips M1 and M2.

In the VRM chip 12, one surface side on which semiconductor integrated circuit E2 is formed is placed in the upward direction (opposite side to memory chip M4). Alternatively, in the VRM chip 12, one surface side on which semiconductor integrated circuit E2 is formed may be placed in the downward direction (side of memory chip M4).

The third and fourth embodiments may be combined.

### (5) Fifth Embodiment

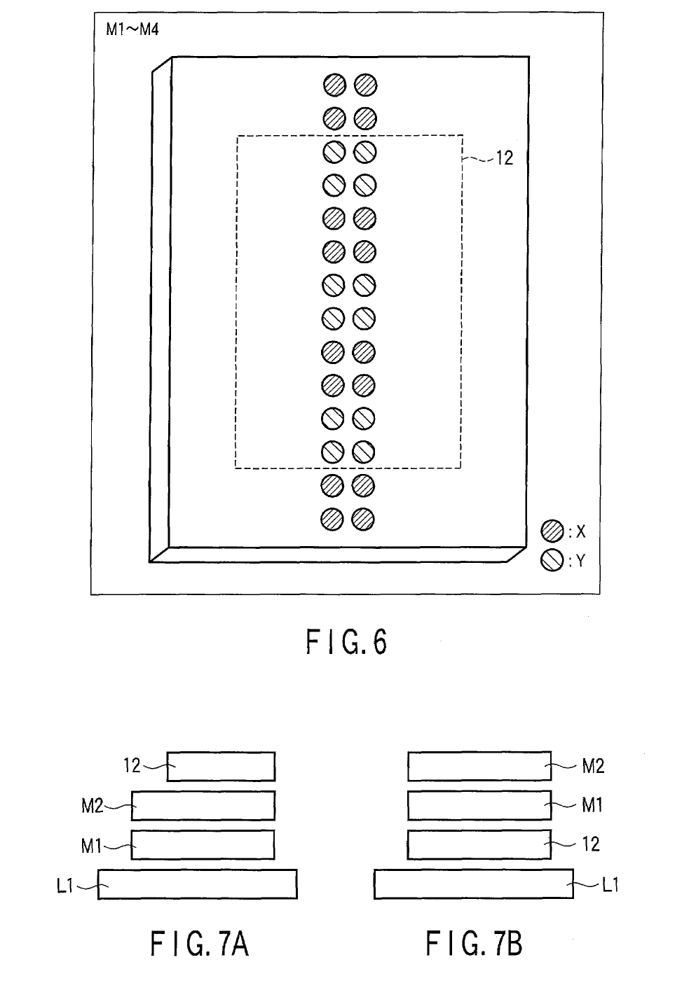

FIG. 6 shows a through-silicon via according to a fifth embodiment of the invention.

The fifth embodiment relates to the position of the through-silicon via of the first to fourth embodiments.

In FIG. 6, “o” indicates the conductive layer (through-silicon via) provided in each of memory chips M1 to M4. The letter “X” corresponds to conductive layer 14(X) in FIGS. 2 to 5 (first to fourth embodiments), and the letter “Y” corresponds to conductive layer 14(Y) in FIGS. 2 to 5.

The positions of through-silicon vias “X” and “Y” depend on the position of the VRM chip 12.

In the fifth embodiment, because the VRM chip 12 is disposed in the center of each of memory chips M1 to M4, through-silicon via “Y” is made in the center of each of memory chips M1 to M4.

However, through-silicon via “X” may be disposed in other portion than the portion in which memory chips M1 to M4 and the VRM chip 12 are overlapped, for example, at an edge of each of memory chips M1 to M4.

### (6) Sixth Embodiment

FIGS. 7A and 7B show a through-silicon via according to a sixth embodiment of the invention.

The sixth embodiment relates to the order in which the chips are stacked.

FIG. 7A shows the chip stacking order corresponding to the first to fifth embodiments. On the other hand, FIG. 7B shows the order in which the size of the VRM chip 12 is greater than or equal to the sizes of memory chips M1 and M2 and less than or equal to the size of control chip L1.

In FIG. 7B, the VRM chip 12 is disposed on control chip L1, and memory chips M1 and M2 are disposed on the VRM chip 12. In this case, memory chips M1 and M2 and the VRM chip 12 are formed into the through-silicon-via chip. The conductive layer (dummy through-silicon via) that is not connected to the semiconductor integrated circuit in the VRM chip 12 is also provided in the VRM chip 12.

### (7) Summary

In the first to sixth embodiments, the specifications, such as the function and layout of the vias, which are suitable for the product, can be provided when the at least three chips having different functions are stacked to make TSV. Therefore, TSV is not just an idea, but can be applied to actual products.

### 4. APPLICATION EXAMPLE

The invention is effectively applied to TSV including at least three chips.

For example, a graphic chip, a DRAM chip, and a VRM chip may be laminated by TSV. A mobile chip, a DRAM chip, and a VRM chip may also be laminated by TSV.

Reduction of package size, low power consumption, and high performance can be realized by TSV compared with a multi-chip module (MCM).

### 5. CONCLUSION

The invention can achieve the versatility of TSV via and decreased production cost.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A through silicon via chip comprising:
a semiconductor substrate having first and second surfaces;
a semiconductor integrated circuit which is provided on the first surface of the semiconductor substrate;
a first conductive layer connecting to the semiconductor integrated circuit, which goes through the first surface of the semiconductor substrate to the second surface of the semiconductor substrate; and
a second conductive layer not connecting to the semiconductor integrated circuit, which goes through the first surface of the semiconductor substrate to the second surface of the semiconductor substrate,
wherein the first and second conductive layers have the same shape and the same structure.

2. The chip according to claim 1,
wherein the second conductive layer is provided at a center of the chip.

3. The chip according to claim 1,
wherein the chip is a memory chip.

4. The chip according to claim 1,
wherein the chip is a control chip.

5. The chip according to claim 1,
wherein the chip is a VRM chip.

6. A stacked chip device comprising:
a first chip having a first function; and
a second chip having a second function which is different from the first function, which is stacked on the first chip,
wherein the first chip is a through-silicon-via chip which is comprised of:
a first semiconductor substrate having first and second surfaces;
a first semiconductor integrated circuit which is provided on the first surface of the first semiconductor substrate;
a first conductive layer connecting to the first semiconductor integrated circuit, which goes through the first surface of the first semiconductor substrate to the second surface of the first semiconductor substrate; and
a second conductive layer not connecting to the first semiconductor integrated circuit, which goes through the first surface of the first semiconductor substrate to the second surface of the first semiconductor substrate,
wherein the first and second conductive layers have the same shape and the same structure,
wherein the second chip is a chip which is comprised of:
a second semiconductor substrate having first and second surfaces; and
a second semiconductor integrated circuit which is provided on the first surface of the second semiconductor substrate,
wherein the second conductive layer of the first chip is connected to the second integrated circuit of the second chip.

7. The device according to claim 6,
wherein the second chip is a through-silicon-via chip which is comprised of a third conductive layer connecting to the second semiconductor integrated circuit, which goes through the first surface of the second semiconductor substrate to the second surface of the second semiconductor substrate.

8. The device according to claim 6,
further comprising a third chip having a third function which is different from the first and second functions,
wherein the first and second chips are stacked on the third chip,
wherein the third chip is a chip which is comprised of:
a third semiconductor substrate having-first and second surfaces; and
a third semiconductor integrated circuit which is provided on the first surface of the third semiconductor substrate,
wherein the second conductive layer of the first chip is connected to the third integrated circuit of the third chip.

9. The device according to claim 8,
wherein the third chip is a through-silicon-via chip which is comprised of a third conductive layer connecting to the third semiconductor integrated circuit, which goes through the first surface of the third semiconductor substrate to the second surface of the third semiconductor substrate.

10. The device according to claim 6, further comprising
a package board having first and second surfaces; and
bumps which is provided on the first surface of the package board,
wherein the first and second chips are provided on the second surface of the package board.

11. The device according to claim 6,
wherein the second conductive layer is provided at a center of the first chip.

12. The device according to claim 6,
wherein each of the first and second chips is a memory chip.

13. The device according to claim 6,
wherein the first chip is a memory chip and the second chip is a VRM chip.

14. The device according to claim 13,
wherein the second chip has a flip chip structure.

15. The device according to claim 8,
wherein each of the first, second and third chips is a memory chip.

16. The device according to claim 8,
wherein each of the first and third chips is a memory chip and the second chip is a VRM chip.

17. The device according to claim 16,
wherein the second chip has a flip chip structure.

18. The device according to claim 8,
wherein each of the first and second chips is a memory chip and the third chip is a control chip.

19. The device according to claim 8,
wherein the first chip is a memory chip, the second chip is a VRM chip and the third chip is a control chip.

20. The device according to claim 9,
wherein the first chip is a memory chip, the second chip is a VRM chip and the third chip is a control chip.
